(19) United States
(12) Patent Application Publication
(10) Pub. No.: US 2015/0177294 A1
(43) Pub. Date: Jun. 25, 2015

(54) METHOD AND DEVICE FOR PROCESSING MAGNETOSTRICTIVE GUIDED WAVE DETECTION SIGNALS

(71) Applicant: Huazhong University of Science and Technology, Wuhan (CN)

(72) Inventors: Xinjun WU, Wuhan (CN); Mingxi TANG, Wuhan (CN); Pengfei SUN, Wuhan (CN)

(21) Appl. No.: 14/538,787

(22) Filed: Nov. 11, 2014

Related U.S. Application Data
(63) Continuation-in-part of application No. PCT/CN2014/079703, filed on Jun. 12, 2014.

(30) Foreign Application Priority Data
Dec. 24, 2013 (CN) 201310723746.0

(51) Int. Cl. G01R 21/133; G01M 99/00

(52) U.S. Cl. CPC G01R 21/133; G01M 99/00

(57) ABSTRACT

A method for processing magnetostrictive guided wave detection signals, including: 1) obtaining an analysis signal by capturing an original magnetostrictive guided wave detection signal; 2) performing band-pass filtering on the analysis signal to obtain a signal, and initializing i to 0; 3) obtaining a group of signals x(i), x(i+1), . . . , x(i+M−1) using a rectangular window with a width of M; 4) forming a matrix A; 5) performing singular value decomposition on the matrix A to obtain a singular matrix B; 6) setting eigenvalues in the matrix B smaller than the median to 0 to obtain a matrix C, and performing inverse singular value transformation on the matrix C to obtain a matrix D; 7) recovering a group of processed signals from the matrix D and calculating energy z of the group of processed signals; and 8) setting i to (i+1) and repeating steps 3)-7) until i=N+1−M.

### CROSS-REFERENCE TO RELATED APPLICATIONS

This application is a continuation-in-part of International Patent Application No. PCT/CN2014/079703 with an international filing date of Jun. 12, 2014, designating the United States, now pending, and further claims priority benefits to Chinese Patent Application No. 201310723746.0 filed Dec. 24, 2013. The contents of all of the aforementioned applications, including any intervening amendments thereto, are incorporated herein by reference. Inquiries from the public to applicants or assignees concerning this document or the related applications should be directed to: Matthias Scholl P. C., Attn.: Dr. Matthias Scholl Esq., 245 First Street, 18^{th} Floor, Cambridge, Mass. 02142.

### BACKGROUND OF THE INVENTION

1. Field of the Invention

The invention relates to a technical field of non-destructive testing, and more particularly to a method and a device for processing magnetostrictive guided wave detection signals.

2. Description of the Related Art

Magnetostrictive guided waves technology has been applied in industry in recent years. However, low conversion efficiency and low signal to noise ratio restrict the applications thereof. In addition, the technology is limited by the use of defect-free samples as standards.

### SUMMARY OF THE INVENTION

In view of the above-mentioned problems, it is an objective of the invention to provide a method and a device for processing magnetostrictive guided wave detection signals. The method obtains an energy distribution of a magnetostrictive guided wave detection signal by suppressing the background noise under certain threshold to reduce the impact of external interference on the signal. The method requires no standard samples and greatly facilitates field application.

To achieve the above objective, in accordance with one embodiment of the invention, there is provided a method for processing magnetostrictive guided wave detection signals, the method operating to improve detection accuracy of magnetostrictive guided waves, and comprising:
S1: obtaining an analysis signal u(n) from capturing an original magnetostrictive guided wave detection signal, where n≦N, and N is the length of the analysis signal u(n);
S2: performing band-pass filtering on the analysis signal u(n) to obtain a signal x(n), and initializing i to 0;
S3: obtaining a group of signals x(i), x(i+1), . . . , x(i+M−1) using a rectangular window with a width of M, where M[L/4], and L is the length of the excitation signal;
S4: forming a matrix A of R*(M−R+1), where R[M/2], and the matrix A is as follows:

$$A = [ \begin{matrix}x ( i ) & x ( i + 1 ) & ⋯ & x ( i + M - R ) \\ x ( i + 1 ) & x ( i + 2 ) & ⋯ & x ( i + M - R + 1 ) \\ ⋮ & ⋮ & ⋱ & ⋮ \\ x ( i + R - 1 ) & x ( i + R ) & ⋯ & x ( i + M - 1 )\end{matrix} ] ;$$

S5: performing singular value decomposition on the matrix A to obtain a singular matrix B, where

$$B = [ \begin{matrix}{λ}_{1} & 0 & ⋯ & 0 & ⋯ & 0 \\ 0 & {λ}_{2} & ⋯ & 0 & ⋯ & 0 \\ ⋮ & ⋮ & ⋱ & ⋮ & ⋮ & ⋮ \\ 0 & 0 & ⋯ & {λ}_{R} & ⋯ & 0\end{matrix} ] ,$$

λⱼ represents an eigenvalue, and j=1, 2, . . . R;
S6: setting eigenvalues in the matrix B smaller than the median to 0 to obtain a matrix C, and performing inverse singular value transformation on the matrix C to obtain a matrix D:

$$D = [ \begin{matrix}y ( i ) & y ( i + 1 ) & ⋯ & y ( i + M - R ) \\ y ( i + 1 ) & y ( i + 2 ) & ⋯ & y ( i + M - R + 1 ) \\ ⋮ & ⋮ & ⋱ & ⋮ \\ y ( i + R - 1 ) & y ( i + R ) & ⋯ & y ( i + M - 1 )\end{matrix} ] ;$$

S7: recovering a group of processed signals y(i), y(i+1), . . . , y(i+M−1) from the matrix D and calculating energy z of the group of processed signals; and
S8: setting i to (i+1) and repeating steps S3-S7 until i=N+1−M, whereby finishing calculation of energy of all processed signals in the selected analysis area.

In a class of the embodiment, the method further comprises:
S9: drawing an energy distribution diagram z(n) according to the energy of processed signals of the selected analysis area obtained by the step S8; and
S10: determining whether a defect exists in a sample according to a distortion characteristic of the energy distribution diagram z(n).

In accordance with another embodiment of the invention, there is provided a device for processing magnetostrictive guided wave detection signals, operable for improving accuracy of magnetostrictive guided wave detection, comprising:

a signal capturing acquiring unit, operable for capturing an original magnetostrictive guided wave detection signal to obtain an analysis signal u(n), where n≦N, and N is the length of the analysis signal u(n);

a band-pass filter, connected to the signal capturing unit and operable for performing band-pass filtering on the analysis signal u(n) to obtain a signal x(n); and

a signal processing unit, connected to the band-pass filter and operable for denoising the signal x(n) and calculating the energy distribution of the denoised signal; where

the signal processing unit operates as follows:

obtaining a group of signals x(i), x(i+1), . . . , x(i+M−1) using a rectangular window with a width of M, where M[L/4], and L is the length of the excitation signal; and initializing i to 0;

forming a matrix A of R*(M−R+1), where R=[M/2]:

$$A = [ \begin{matrix}x ( i ) & x ( i + 1 ) & … & x ( i + M - R ) \\ x ( i + 1 ) & x ( i + 2 ) & … & x ( i + M - R + 1 ) \\ ⋮ & ⋮ & ⋱ & ⋮ \\ x ( i + R - 1 ) & x ( i + R ) & … & x ( i + M - 1 )\end{matrix} ] ;$$

performing singular value decomposition on the matrix A to obtain a singular matrix B:

$$B = [ \begin{matrix}{λ}_{1} & 0 & … & 0 & … & 0 \\ 0 & {λ}_{2} & … & 0 & … & 0 \\ ⋮ & ⋮ & ⋱ & ⋮ & ⋮ & ⋮ \\ 0 & 0 & … & {λ}_{R} & … & 0\end{matrix} ] ,$$

λⱼ represents an eigenvalue, and j=1, 2, . . . R;

setting eigenvalues in the matrix B smaller than the median to 0 to obtain a matrix C, and performing inverse singular value transformation on the matrix C to obtain a matrix D:

$$D = [ \begin{matrix}y ( i ) & y ( i + 1 ) & … & y ( i + M - R ) \\ y ( i + 1 ) & y ( i + 2 ) & … & y ( i + M - R + 1 ) \\ ⋮ & ⋮ & ⋱ & ⋮ \\ y ( i + R - 1 ) & y ( i + R ) & … & y ( i + M - 1 )\end{matrix} ] ;$$

recovering a group of processed signals y(i), y(i+1), y(i+M−1) from the matrix D and calculating energy z of the group of processed signals; and

setting i to (i+1) and repeating the steps of obtaining a group of signals x(i), x(i+1), . . . , x(i+M−1) using a rectangular window with a width of M and processing the signals until i=N+1−M, whereby finishing calculation of energy of all processed signals in the selected analysis area.

In a class of the embodiment, the device further comprises a defect detecting unit, connected to the signal processing unit, and operable for drawing an energy distribution diagram z(n) according to the energy of processed signals of the selected analysis area and determining whether a defect exists in a test sample according to a distortion characteristic of the energy distribution diagram z(n).

The principle of the invention is that a magnetostrctve guided wave propagating in a sample at a group velocity is reflected, diffracted or transmitted in a different way due to existence of defects and other irregular structures which causes changes in the signal waveform and the propagating energy in corresponding positions. In the prior art, a defect-free sample is required for collecting a standard signal, and differential and other processes should be carried out on a test signal and the standard signal, which is unfavorable for field detection. However, the invention obtains an energy distribution of a magnetostrictive guided wave detection signal by suppressing the background noise under certain threshold to reduce the impact of external interference on the signal, so that the accuracy of magnetostrictive guided wave signal detection is improved by improving the signal to noise ratio. The method requires no standard samples and greatly facilitates field application.

### BRIEF DESCRIPTION OF THE DRAWINGS

FIG. 1 is a flow chart of a method for processing magnetostrictive guided wave detection signals according to one embodiment of the invention;

FIG. 2 is a schematic diagram of a device for processing magnetostrictive guided wave detection signals according to one embodiment of the invention;

FIG. 3 is an experimental layout for detecting a defective standard pipe according to one embodiment of the invention;

FIG. 4 is a schematic diagram of an original signal detected from a defective pipe with an outside diameter of 25 mm and an inside diameter of 20 mm according to one embodiment of the invention;

FIG. 5 is a schematic diagram of an analysis signal obtained by capturing an original signal detected from a defective pipe;

FIG. 6 is an energy distribution diagram of signals obtained by processing an analysis signal of a defective pipe by the method of the invention;

FIG. 7 is an experimental layout for detecting a defect-free standard pipe according to one embodiment of the invention;

FIG. 8 is a schematic diagram of an original signal detected from a defect-free pipe with an outside diameter of 25 mm and an inside diameter of 20 mm;

FIG. 9 is a schematic diagram of an analysis signal obtained by capturing an original signal detected from a defect-free pipe; and

FIG. 10 is an energy distribution diagram of signals obtained by processing an analysis signal of a defect-free pipe by the method of the invention.

### DETAILED DESCRIPTION OF THE EMBODIMENTS

For clear understanding of the objectives, features and advantages of the invention, detailed description of the invention will be given below in conjunction with accompanying drawings and specific embodiments. It should be noted that the examples are only meant to explain the invention, and not to limit the scope of the invention.

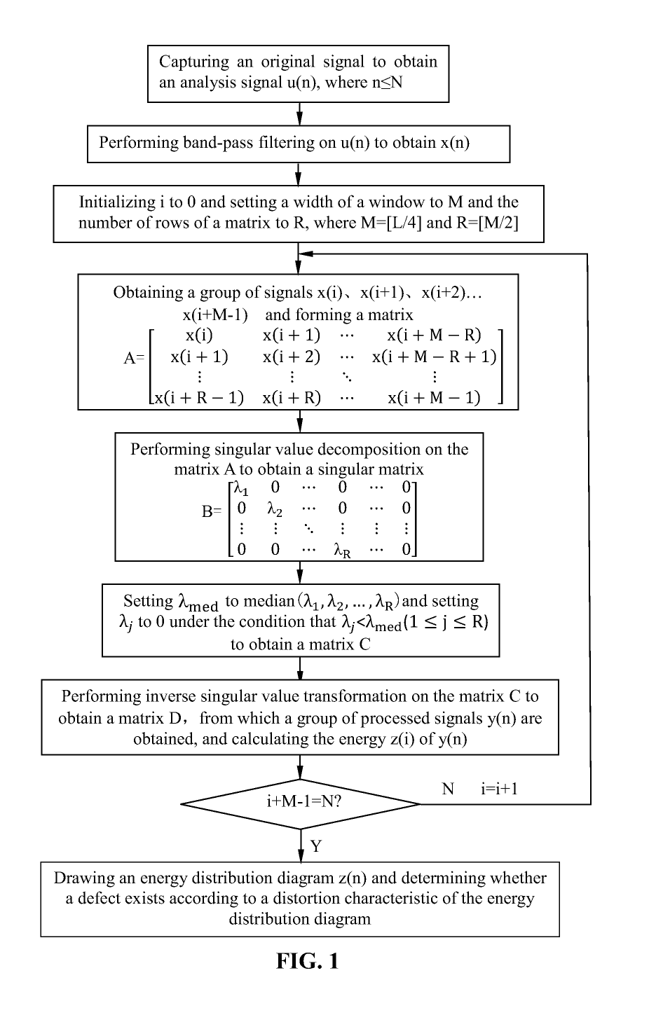

FIG. 1 is a flow chart of a method for improving accuracy of magnetostrictive guided wave detection according to the invention. As shown in FIG. 1, the method for improving accuracy of magnetostrictive guided wave detection comprises steps of:

S1: obtaining an analysis signal u(n) from capturing an original magnetostrictive guided wave detection signal, where n≦N, and N is the length of the analysis signal u(n);

S2: performing band-pass filtering on the analysis signal u(n) to obtain a signal x(n), and initializing i to 0;

S3: obtaining a group of signals x(i), x(i+1), . . . , x(i+M−1) using a rectangular window with a width of M, where M[L/4], and L is the length of the excitation signal;

S4: forming a matrix A of R*(M−R+1), where R[M/2]:

$$A = [ \begin{matrix}x ( i ) & x ( i + 1 ) & … & x ( i + M - R ) \\ x ( i + 1 ) & x ( i + 2 ) & … & x ( i + M - R + 1 ) \\ ⋮ & ⋮ & ⋱ & ⋮ \\ x ( i + R - 1 ) & x ( i + R ) & … & x ( i + M - 1 )\end{matrix} ] ;$$

S5: performing singular value decomposition on the matrix A to obtain a singular matrix B:

$$B = [ \begin{matrix}{λ}_{1} & 0 & … & 0 & … & 0 \\ 0 & {λ}_{2} & … & 0 & … & 0 \\ ⋮ & ⋮ & ⋱ & ⋮ & ⋮ & ⋮ \\ 0 & 0 & … & {λ}_{R} & … & 0\end{matrix} ] ,$$

λⱼ represents an eigenvalue, and j=1, 2, . . . R;

S6: setting λ_{med} to median(λ₁, λ₂, . . . , λ_{R}) and setting λⱼ to 0 under the condition that λⱼ<λ_{med} (1≦j≦R) to obtain a matrix C, namely setting eigenvalues in the matrix B smaller than the median to 0 to obtain the matrix C; and performing inverse singular value transformation on the matrix C to obtain a matrix D:

$$D = [ \begin{matrix}y ( i ) & y ( i + 1 ) & … & y ( i + M - R ) \\ y ( i + 1 ) & y ( i + 2 ) & … & y ( i + M - R + 1 ) \\ ⋮ & ⋮ & ⋱ & ⋮ \\ y ( i + R - 1 ) & y ( i + R ) & … & y ( i + M - 1 )\end{matrix} ] ;$$

S7: recovering a group of processed signals y(i), y(i+1), y(i+M−1) from the matrix D and calculating energy z of the group of processed signals;

S8: setting i to (i+1) and repeating steps S3-S7 until i=N+1−M, whereby finishing calculation of energy of all processed signals in the selected analysis area;

S9: drawing an energy distribution diagram z(n) according to the energy of processed signals of the selected analysis area obtained by the step S8; and

S10: determining whether a defect exists in a sample according to a distortion characteristic of the energy distribution diagram z(n).

FIG. 2 is a schematic diagram of a device for processing magnetostrictive guided wave detection signals according to the invention. As shown in FIG. 2, the device for processing magnetostrictive guided wave detection signals comprises a signal capturing unit 1, a band-pass filter 2 connected to the signal capturing unit 1, a signal processing unit 3 connected to the band-pass filter 2, and a defect detecting unit 4 connected to the signal processing unit 3. The signal capturing unit 1 is operable for capturing an original magnetostrictive guided wave detection signal to obtain an analysis signal u(n), where n≦N, and N is the length of the analysis signal u(n). The band-pass filter 2 is operable for performing band-pass filtering on the analysis signal u(n) to obtain a signal x(n). The signal processing unit 3 is operable for denoising the signal x(n) and calculating the energy distribution of the denoised signal, where the signal processing unit 3 operates as follows:

obtaining a group of signals x(i), x(i+1), . . . , x(i+M−1) using a rectangular window with a width of M, where M[L/4], and L is the length of the excitation signal; and initializing i to 0;

forming a matrix A of R*(M−R+1), where R[M/2]:

$$A = [ \begin{matrix}x ( i ) & x ( i + 1 ) & … & x ( i + M - R ) \\ x ( i + 1 ) & x ( i + 2 ) & … & x ( i + M - R + 1 ) \\ ⋮ & ⋮ & ⋱ & ⋮ \\ x ( i + R - 1 ) & x ( i + R ) & … & x ( i + M - 1 )\end{matrix} ] ;$$

performing singular value decomposition on the matrix A to obtain a singular matrix B:

$$B = [ \begin{matrix}{λ}_{1} & 0 & … & 0 & … & 0 \\ 0 & {λ}_{2} & … & 0 & … & 0 \\ ⋮ & ⋮ & ⋱ & ⋮ & ⋮ & ⋮ \\ 0 & 0 & … & {λ}_{R} & … & 0\end{matrix} ] ,$$

λⱼ represents an eigenvalue, and j=1, 2, . . . R;

setting eigenvalues in the matrix B smaller than the median to 0 to obtain a matrix C, and performing inverse singular value transformation on the matrix C to obtain a matrix D:

$$D = [ \begin{matrix}y ( i ) & y ( i + 1 ) & … & y ( i + M - R ) \\ y ( i + 1 ) & y ( i + 2 ) & … & y ( i + M - R + 1 ) \\ ⋮ & ⋮ & ⋱ & ⋮ \\ y ( i + R - 1 ) & y ( i + R ) & … & y ( i + M - 1 )\end{matrix} ] ;$$

recovering a group of processed signals y(i), y(i+1), y(i+M−1) from the matrix D and calculating energy z of the group of processed signals; and

setting i to (i+1) and repeating the steps of obtaining a group of signals x(i), x(i+1), . . . , x(i+M−1) using a rectangular window with a width of M and processing the signals until i=N+1−M, whereby finishing calculation of energy of all processed signals in the selected analysis area.

The defect detecting unit 4 is operable for drawing an energy distribution diagram z(n) according to the energy of processed signals of the selected analysis area and determining whether a defect exists in a test sample according to a distortion characteristic of the energy distribution diagram z(n).

A specific embodiment is provided below according to the invention.

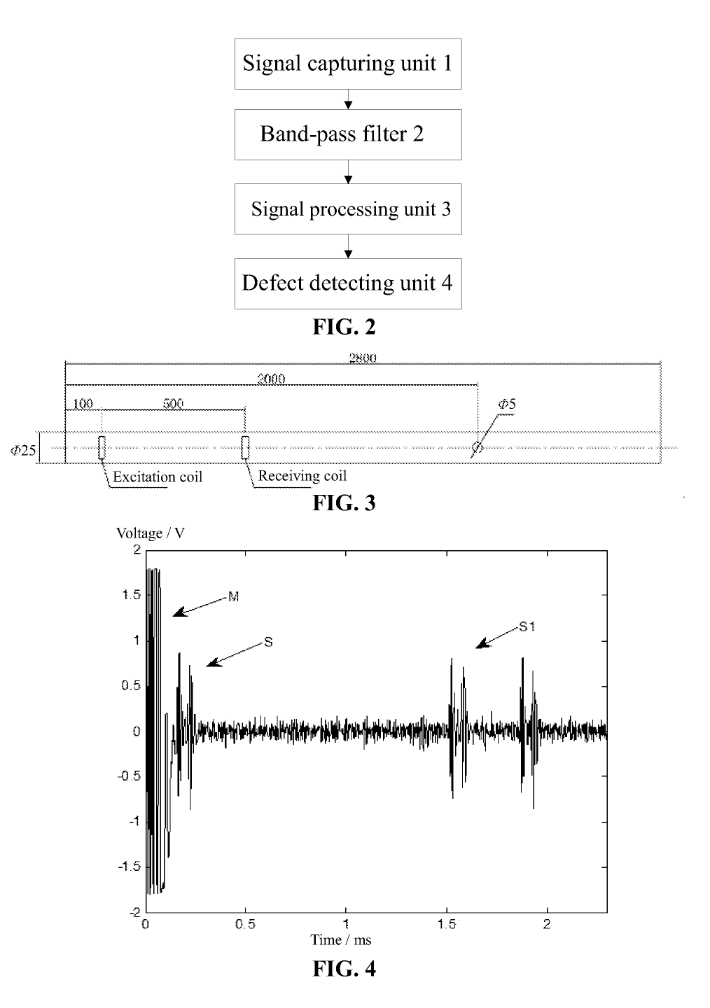

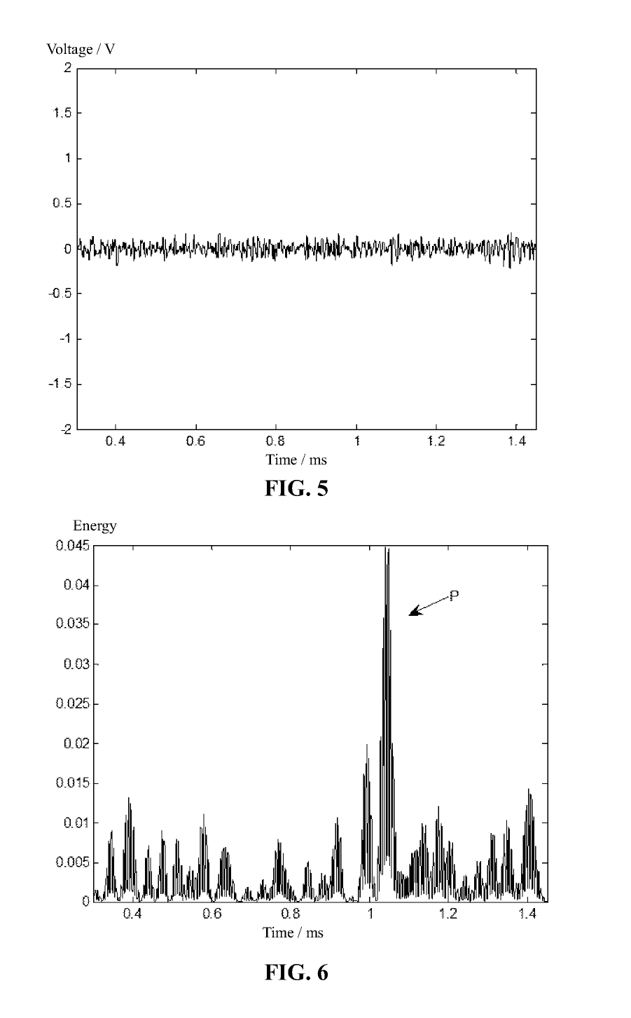

As shown in FIG. 3, a defective heat exchange pipe with an outside diameter of 25 mm, an inside diameter of 20 mm, and a length of 2800 mm is used as a test sample. An excitation coil is 100 mm away from the left end of the pipe, a receiving coil is 600 mm away from the left end of the pipe, and a hole with a diameter of 5 mm exists 2000 mm away from the left end of the pipe. The excitation frequency is 90 kHz, the sampling frequency is 2000 kHz, and the guided wave speed is about 3200 m/s. A schematic diagram of an original signal detected from the defective heat exchange pipe is shown in FIG. 4, which includes an electromagnetic pulse signal M, a signal S passed through a receiving sensor for the first time, and a signal S1 reflected by the right end for the first time. In order to facilitate analysis, the original signal in FIG. 4 is cut to obtain an analysis signal of the defective pipe ranging from S to S1, which is shown in FIG. 5. A defective signal should exist when t equals 1.03 ms according to calculation, which cannot be identified according to FIG. 5. The analysis signal of the defective pipe is processed by the method of the present invent by selecting a rectangular window with a width of 6 and forming a matrix of 3*4. FIG. 6 is an energy distribution diagram of signals obtained by processing the analysis signal of the defective pipe by the method of the invention. As shown in FIG. 6, a significant distortion P occurs in the energy at 1.03 ms and the peak value of P mutates greatly. The occurring time matches with the theoretical time, so that it can be concluded that the distortion is caused by the defection.

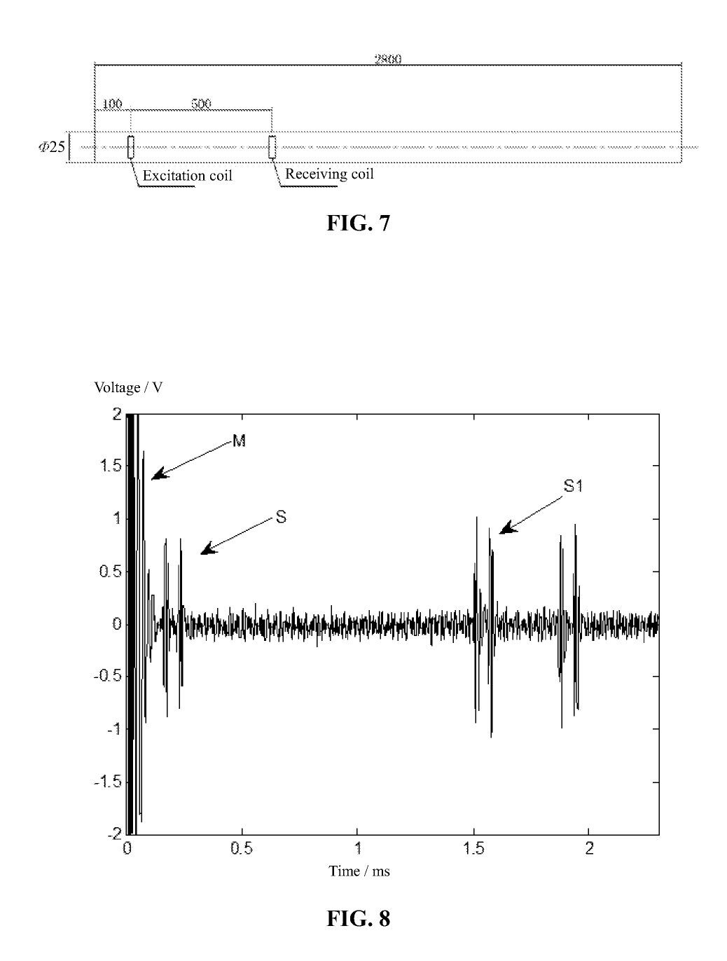

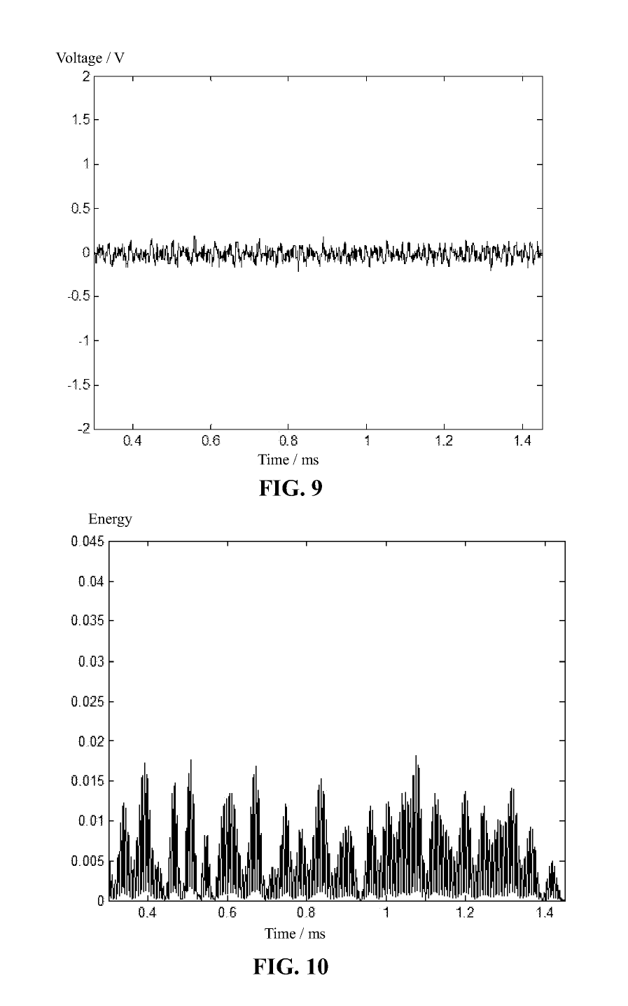

A defect-free heat exchange pipe having the same specifications with the defective heat exchange pipe is provided. The experimental layout, the excitation frequency, the sampling frequency and the guided wave speed stay unchanged. FIG. 7 is the experimental layout for detecting the defect-free pipe. FIG. 8 is a schematic diagram of an original signal detected from the defect-free pipe, which is cut to obtain an analysis signal of the defect-free pipe ranging from S to S1. FIG. 9 is a schematic diagram of the analysis signal obtained by capturing the original signal detected from the defect-free pipe. FIG. 10 is an energy distribution diagram of signals obtained by processing the analysis signal of a defect-free pipe by the method of the invention, unlike the energy distribution diagram of the defective pipe (FIG. 6), no obvious distortion occurs. Therefore, it can be concluded that the method of the invention is effective and reliable.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. A method for processing magnetostrictive guided wave detection signals, the method comprising:
S1: obtaining an analysis signal u(n) by capturing an original magnetostrictive guided wave detection signal, where n≦N, and N is the length of the analysis signal u(n);
S2: performing band-pass filtering on the analysis signal u(n) to obtain a signal x(n), and initializing i to 0;
S3: obtaining a group of signals x(i), x(i+1), . . . , x(i+M−1) using a rectangular window with a width of M, where M[L/4], and L is the length of the excitation signal;
S4: forming a matrix A of R*(M−R+1), where R[M/2]:
$$A = [ \begin{matrix}x ( i ) & x ( i + 1 ) & … & x ( i + M - R ) \\ x ( i + 1 ) & x ( i + 2 ) & … & x ( i + M - R + 1 ) \\ ⋮ & ⋮ & ⋱ & ⋮ \\ x ( i + R - 1 ) & x ( i + R ) & … & x ( i + M - 1 )\end{matrix} ] ;$$
S5: performing singular value decomposition on the matrix A to obtain a singular matrix B:
$$B = [ \begin{matrix}{λ}_{1} & 0 & … & 0 & … & 0 \\ 0 & {λ}_{2} & … & 0 & … & 0 \\ ⋮ & ⋮ & ⋱ & ⋮ & ⋮ & ⋮ \\ 0 & 0 & … & {λ}_{R} & … & 0\end{matrix} ] ,$$
λⱼ represents an eigenvalue, and j=1, 2, . . . R;
S6: setting eigenvalues in the matrix B smaller than the median to 0 to obtain a matrix C, and performing inverse singular value transformation on the matrix C to obtain a matrix D:
$$D = [ \begin{matrix}y ( i ) & y ( i + 1 ) & … & y ( i + M - R ) \\ y ( i + 1 ) & y ( i + 2 ) & … & y ( i + M - R + 1 ) \\ ⋮ & ⋮ & ⋱ & ⋮ \\ y ( i + R - 1 ) & y ( i + R ) & … & y ( i + M - 1 )\end{matrix} ] ;$$
S7: recovering a group of processed signals y(i), y(i+1), . . . , y(i+M−1) from the matrix D and calculating energy z of the group of processed signals; and
S8: setting i to (i+1) and repeating steps S3-S7 until i=N+1−M, whereby finishing calculation of energy of all processed signals in the selected analysis area.

2. The method of claim 1, further comprising:
S9: drawing an energy distribution diagram z(n) according to the energy of processed signals of the selected analysis area obtained by the step S8; and
S10: determining whether a defect exists in a sample according to a distortion characteristic of the energy distribution diagram z(n).

3. A device for processing magnetostrictive guided wave detection signals, the device comprising:
1) a signal capturing unit, operable for capturing an original magnetostrictive guided wave detection signal to obtain an analysis signal u(n), where n≦N, and N is the length of the analysis signal u(n);
2) a band-pass filter, connected to the signal capturing unit and operable for performing band-pass filtering on the analysis signal u(n) to obtain a signal x(n); and
3) a signal processing unit, connected to the band-pass filter and operable for denoising the signal x(n) and calculating the energy distribution of the denoised signal;
wherein the signal processing unit operates as follows:
a) obtaining a group of signals x(i), x(i+1), . . . , x(i+M−1) using a rectangular window with a width of M, where M[L/4], and L is the length of the excitation signal, and initializing i to 0;
b) forming a matrix A of R*(M−R+1), where R=[M/2]:
$$A = [ \begin{matrix}x ( i ) & x ( i + 1 ) & … & x ( i + M - R ) \\ x ( i + 1 ) & x ( i + 2 ) & … & x ( i + M - R + 1 ) \\ ⋮ & ⋮ & ⋱ & ⋮ \\ x ( i + R - 1 ) & x ( i + R ) & … & x ( i + M - 1 )\end{matrix} ] ;$$
c) performing singular value decomposition on the matrix A to obtain a singular matrix B:
$$B = [ \begin{matrix}{λ}_{1} & 0 & … & 0 & … & 0 \\ 0 & {λ}_{2} & … & 0 & … & 0 \\ ⋮ & ⋮ & ⋱ & ⋮ & ⋮ & ⋮ \\ 0 & 0 & … & {λ}_{R} & … & 0\end{matrix} ] ,$$
λⱼ represents an eigenvalue, and j=1, 2, . . . R;
d) setting eigenvalues in the matrix B smaller than the median to 0 to obtain a matrix C, and performing inverse singular value transformation on the matrix C to obtain a matrix D:
$$D = [ \begin{matrix}y ( i ) & y ( i + 1 ) & … & y ( i + M - R ) \\ y ( i + 1 ) & y ( i + 2 ) & … & y ( i + M - R + 1 ) \\ ⋮ & ⋮ & ⋱ & ⋮ \\ y ( i + R - 1 ) & y ( i + R ) & … & y ( i + M - 1 )\end{matrix} ] ;$$
e) recovering a group of processed signals y(i), y(i+1), . . . , y(i+M−1) from the matrix D and calculating energy z of the group of processed signals; and
f) setting i to (i+1) and repeating the steps of obtaining a group of signals x(i), x(i+1), . . . , x(i+M−1) using a rectangular window with a width of M and processing the signals until i=N+1−M, whereby finishing calculation of energy of all processed signals in the selected analysis area.

4. The device of claim 3, further comprising a defect detecting unit connected to the signal processing unit, and operable for drawing an energy distribution diagram z(n) according to the energy of processed signals of the selected analysis area and determining whether a defect exists in a test sample according to a distortion characteristic of the energy distribution diagram z(n).
